(19) United States
(12) Patent Application Publication
(10) Pub. No.: US 2012/0205695 A1
(43) Pub. Date: Aug. 16, 2012

(54) LIGHT-EMITTING DIODE DEVICE

(76) Inventors: Tzu-Han Lin, Zhubei City (TW); Izy-Ying Lin, Hsinchu City (TW); Ming-Nan Lin, Hsinchu City (TW)

(21) Appl. No.: 13/028,809

(22) Filed: Feb. 16, 2011

(51) Int. Cl. H01L 33/44

(52) U.S. Cl. 257/98; 257/E33.061

(57) ABSTRACT

A light-emitting diode device is provided, including a submount, a light-emitting diode (LED) chip mounted on the submount, a first transparent insulating layer formed on the submount and the LED chip, a transparent conductive layer formed on the first transparent insulating layer, a phosphor layer formed on the first transparent conductive layer covering the LED chip, and a transparent passivation layer formed on the phosphor layer and over the transparent conductive layer.

### BACKGROUND OF THE INVENTION

1. Field of the Invention

The invention relates to light emitting devices, and more particularly to light-emitting diode (LED) devices having a light-emitting diode (LED) chip with an improved phosphor coating thereover and improved electrical reliability thereof.

2. Description of the Related Art

Light-emitting diode (LED) devices are solid-state light sources with multiple-advantages. They are capable of reliably providing light with high brightness and thus are applied in displays, traffic lights and indicators. LED devices typically include an LED die electrically bonded on a support substrate and the LED die may have an n-contact formed on one side and a p-contact formed on the opposite side therein or have both contacts formed on the same side therein.

To improve light output efficiency of an LED device, uniform light output performances of the LED device needs to be improved. U.S. Pat. No. 6,576,488, issued to Collins, III et al. discloses methods for conformally coating phosphors over an LED chip by selective electrophoretic phosphor deposition processes to thereby produce uniform light output from the LED chip.

However, in U.S. Pat. No. 6,576,488, the p-contact and the n-contact of the LED chip disclosed therein are exposed (e.g. see FIG. 4E therein) or electrically connected by an electrically conductive film (e.g see FIG. 6E therein) during the selective electrophoretic phosphor deposition process. This is undesired since shorts may be happen to the LED chip during the selective electrophoretic phosphor deposition process, thereby ruining electrical reliability of the LED chip.

In addition, in U.S. Pat. No. 6,576,488, the phosphor particles are deposited over the LED chip at a relative slow deposition rate during the selective electrophoretic phosphor deposition process, wherein some of the charged phosphor particles coated over the LED chip may crack and peel off from the LED chip, thereby causing light to be output by various portions of the LED chip.

Therefore, there is a need for a novel LED device addressing the above problems.

### BRIEF SUMMARY OF THE INVENTION

Light-emitting diode (LED) devices having light-emitting diode (LED) chips with an improved phosphor coating formed thereover and improved electrical reliability thereof are provided.

An exemplary light-emitting diode device comprises a submount, a light-emitting diode (LED) chip mounted on the submount, a first transparent insulating layer formed on the submount and the LED chip, a transparent conductive layer formed on the first transparent insulating layer, a phosphor layer formed on the first transparent conductive layer covering the LED chip, and a transparent passivation layer formed on the phosphor layer and over the transparent conductive layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1-5, and 7 are cross sections showing a method for fabricating a light-emitting diode (LED) device according to an embodiment of the invention;

FIG. 6 is a schematic view showing an enlargement of a region 124 shown in FIG. 5; and

FIG. 8 is a cross section showing a light-emitting diode (LED) device according to an exemplary embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

As used herein, “LED chip” refers to a stack of semiconductor layers, including an active region which emits light when biased to produce an electrical current flow through the device, and contacts attached to the stack. If a substrate on which the semiconductor layers are grown is present, “LED chip” includes the substrate. “Phosphor” refers to any luminescent materials which absorb light of one wavelength and emits light of a different wavelength. “Submount,” used herein, refers to a secondary support substrate other than the substrate on which the epitaxial layers of an LED chip are grown.

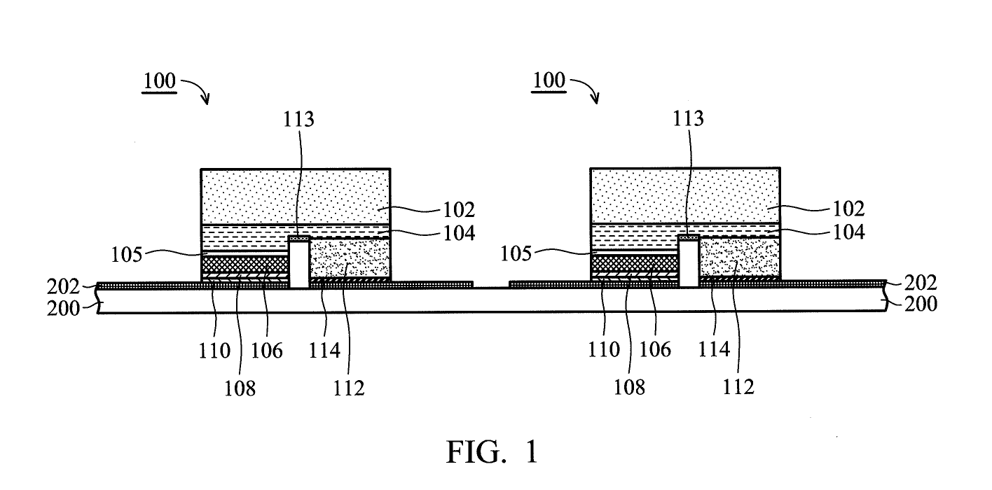

FIGS. 1-5, and 7 are cross sections showing an exemplary method for fabricating a light-emitting diode (LED) device.

In FIG. 1, a submount 200 with a plurality of light-emitting diode (LED) chips 100 mounted thereon is first provided. The submount 200 is provided with a plurality of patterned bonding layers 202, and the plurality of LED chips 100 are respectively and adequately mounted on the bonding layers 202 according to a flip-chip configuration. The bonding layers 202 can be, for example, layers of copper.

In this embodiment, each of the plurality of the LED chips 100 comprises a substrate 102, an n-type region 104 formed on the substrate 102, an active region 105 formed on a portion of the n-type region 104, a p-type region 106 formed on the active region 105, a p-contact 108 formed on the p-type region 106, an n-contact 112 formed on another portion of the n-type region 104, and a reflective layer 113 formed on a portion of the n-type region 104 adjacent to the n-contact 112. The p-contact 108 and the n-contact 112 of the LED chips 100 are mounted on the die bonding layers 202 by connection means 110 and 114. The LED chips 100 can be formed by conventional methods and fabrication thereof are not described here in detail.

In one embodiment, the substrate 102 may comprise a nonconductive material such as sapphire, undoped silicon carbide (SiC), undoped III-nitride, or an undoped II-VI material. Alternatively, the substrate 102 may include a conductive material such as doped SiC, doped III-nitride, or a doped II-VI material. The p-type region 106 may comprise multiple layer structures of materials having the general formula AlₓGa_{y}In_{1-x-y}N (0.1≦x≦1, 0≦y≦1, x+y≦1), and may further contain group III elements such as boron and thallium. Sometimes, the nitrogen may be replaced by phosphorus, arsenic, antimony, or bismuth. In some embodiments, the n-type region 104, the active region 105, and the p-type region 108 may be composed of an II-VI material. The connective means 110 and 112 can be, for example, any conventional adhesive or metal bumps such as solder, gold, or aluminum bumps. The LED chips 100 cause light to exit through all surfaces except the surfaces which are attached to the submount 200, obstructed by metallization (not shown), or obstructed by the reflective layer 113.

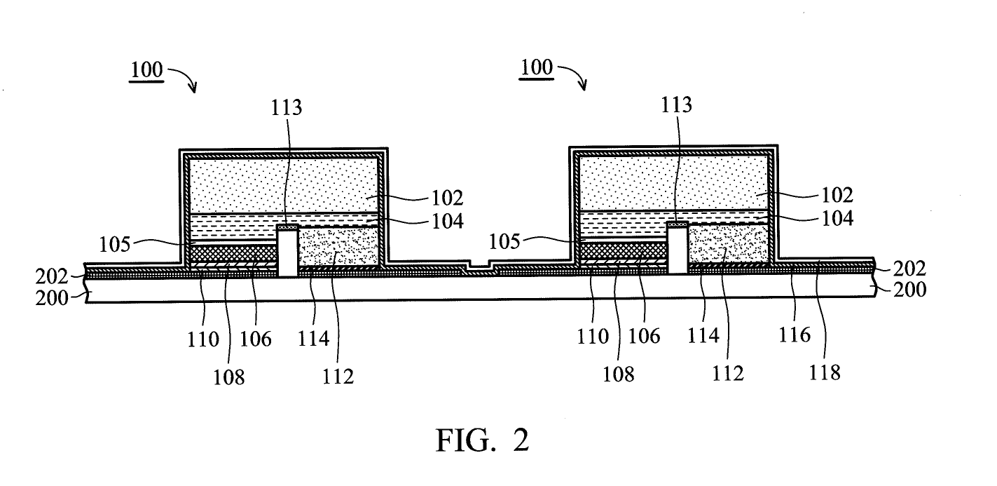

In FIG. 2, a transparent insulating layer 116 is next formed on the submount 200, the bonding layers 202, and the LED chips 100. The transparent insulating layer 116 covers exposed surfaces of the submount 200, the bonding layers 202, and the LED chips 100 to thereby electrically isolate the n-contact 112 of the LED chips 100 from the p-contact 106 of the LED chips 100. The transparent insulating layer 116 may comprise insulating materials such as silicon-based or fluorine-based materials, and can be formed with a thickness of about 0.1-10 μm. The transparent insulating layer 116 can be formed by, for example, spray deposition or immersion deposition. A transparent conductive layer 118 is then formed on the transparent insulating layer 116. The transparent conductive layer 118 may comprise transparent conductive materials such as indium tin oxide (ITO), aluminum oxide (ATO), zinc oxide, or the like, and can be formed with a thickness of about 0.1-10 μm. The transparent conductive layer 118 can be formed by, for example, physical vapor deposition.

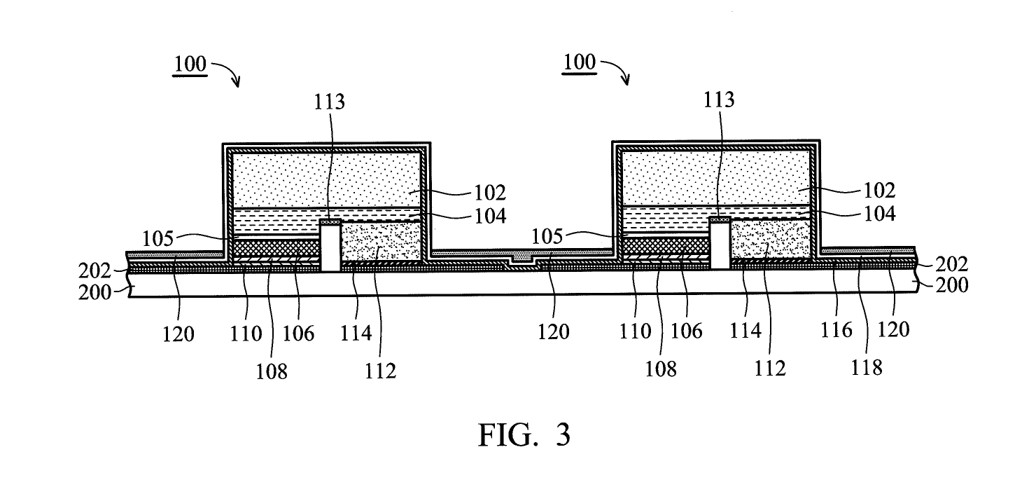

In FIG. 3, another transparent insulating layer 120 is formed on the transparent conductive layer 118 covering the submount 200. However, the transparent insulating layer 120 is not form on the transparent conductive layer 118 covering the LED chips 100, thereby defining a region over the LED chips 100 for sequential phosphor coatings. The transparent insulating layer 120 may comprise transparent insulating materials such as silicon-based or fluorine-based materials and can be formed with a thickness of about 0.1-10 μm. The transparent insulating layer 120 can be formed by, for example, spray deposition or immersion deposition.

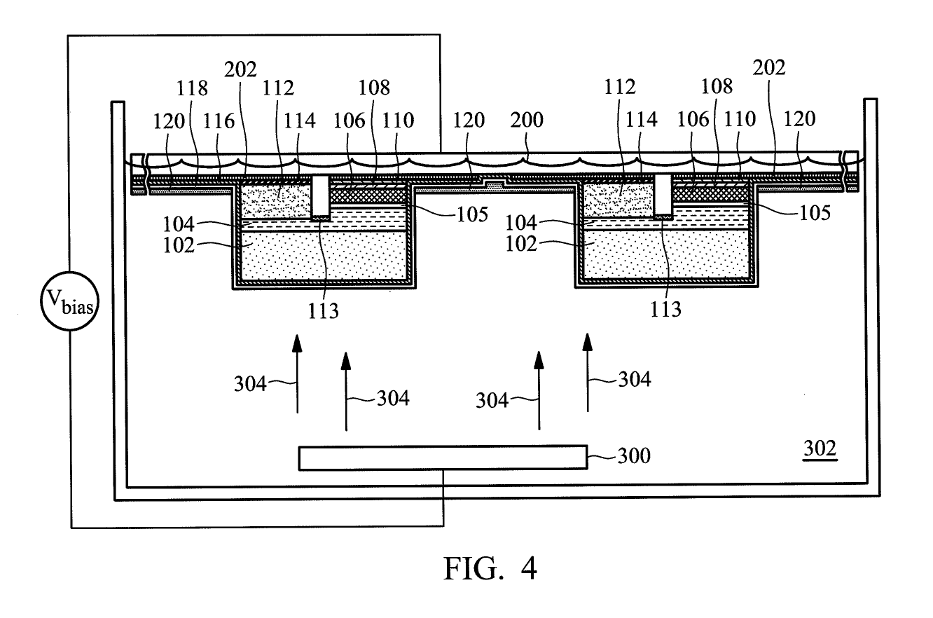

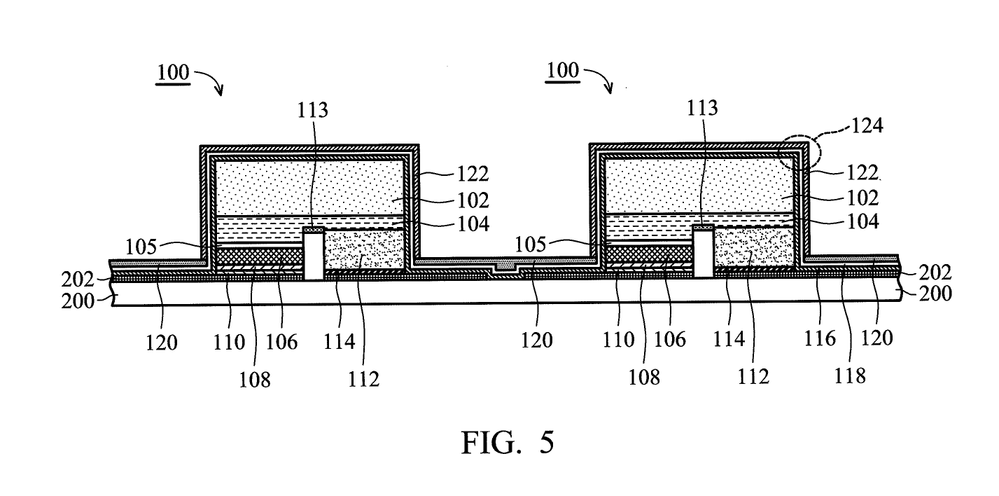

In FIG. 4, the structure shown in FIG. 3 is then immersed in a solution 302 and different biases are applied to the submount 200 and an electrode 300, as indicated by V_{bias} to perform an electrophoresis process for forming a phosphor layer over the LED chips 100. The electrode 300 and exposed surfaces of the transparent conductive layer 118 are immersed in the solution 302 of phosphor particles entirely coated with a transparent conductive layer thereover. Although FIG. 4 shows the electrode 300 to be physically separate from the container that holds the solution 302, the electrode 300 includes all means of charging the phosphor particles, and may be integrated with another component, such as the container. The solution 302 may contain a binder material and/or a charging agent in addition to phosphor particles. An exemplary solution 302 may include isopropyl alcohol, oxalic acid (as a charging agent), and phosphor particles entirely coated with transparent conductive materials such as ITO, ATO or ZnO thereover. However, the solution 302 may not include water to improve adhesion of the phosphor particles entirely coated with the transparent conductive material thereover to the transparent conductive layer 118. The phosphor particles can be, for example, strontium sulfide compounds and yttrium aluminum garnet compounds, but are not limited thereto. The electric field created by the bias voltages pushes the phosphor particles entirely coated with the transparent conductive material thereover out of the solution 302 in the direction shown by the arrows 304. Although the phosphor-bearing solution 302 comes in contact with the transparent insulating layers 120 over the submount 200 and the LED chip 100, phosphor particles entirely coated with the transparent conductive material thereover are deposited only on conductive surfaces of the transparent conductive layer 118. After the deposition, a phosphor layer 122 is precisely and selectively coated on the transparent conductive layer 118 covering the LED chips 100, as shown in FIG. 5. In one embodiment, the phosphor layer 122 is formed with a thickness of about 10-200 μm. Moreover, since the n-contact 112 of the LED chips 100 is isolated from the p-contact 106 of the LED chips 100 by the transparent insulating layer 116, the n-contact 112 of the LED chips 100 and the p-contact 106 of the LED chips 100 will not short during the electrophoresis process for forming the phosphor layer 122, and the electrical reliabilities of the LED chips are maintained after the electrophoresis process.

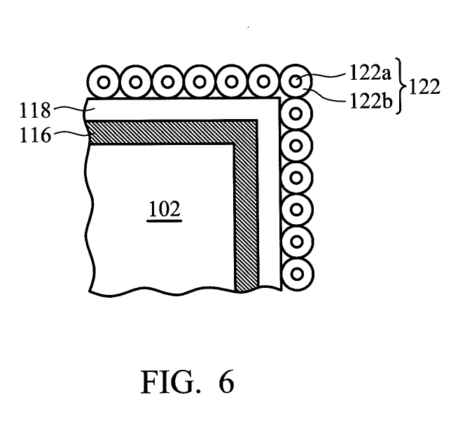

FIG. 6 is a schematic view showing an enlargement of a region 124 shown in FIG. 5. As shown in FIG. 6, the phosphor layer 122 comprises at least one layer of phosphor particles 122a entirely coated with a layer of transparent conductive material 122b such as ITO, ATO, ZnO, or the like over exposed surfaces thereof. In one embodiment, the phosphor particles 122a of the phosphor layer 122 have diameters of about 1-20 μm, and the transparent conductive material 122b of the phosphor layer 122 has a thickness of about 0.1-2.0 μm

Through formations of the transparent conductive material 122b, the phosphor particles 122a can be electrically deposited over the exposed surfaces of the transparent conductive layer 118 at a faster speed when compared with there is no transparent conductive material 122b formed over the phosphor particles 122a. In addition, the phosphor layer 122 will not peel off easily from the exposed surface of the transparent conductive layer 118 due to better adhesion between the transparent conductive layer 118 and the transparent conductive materials 122b of the phosphor layer 122.

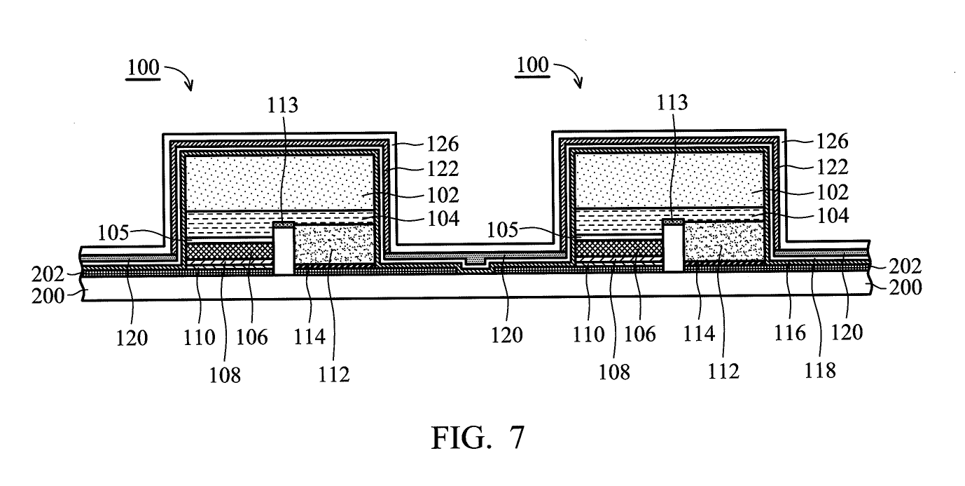

In FIG. 7, a transparent passivation layer 126 is then formed on the transparent insulating layer 120 and the phosphor layer 122 to further ensure adhesion of the phosphor layer 122 over the LED chips 100, and an LED device with improved and uniform phosphor coating formed thereover and improved electrical reliability is thus obtained. A light-out efficiency of the LED device shown in FIG. 7 is thus improved. In one embodiment, the transparent passivation layer 126 may comprise materials such as silicon-based or fluorine-based materials, having a thickness of about 1 μm to 1 mm.

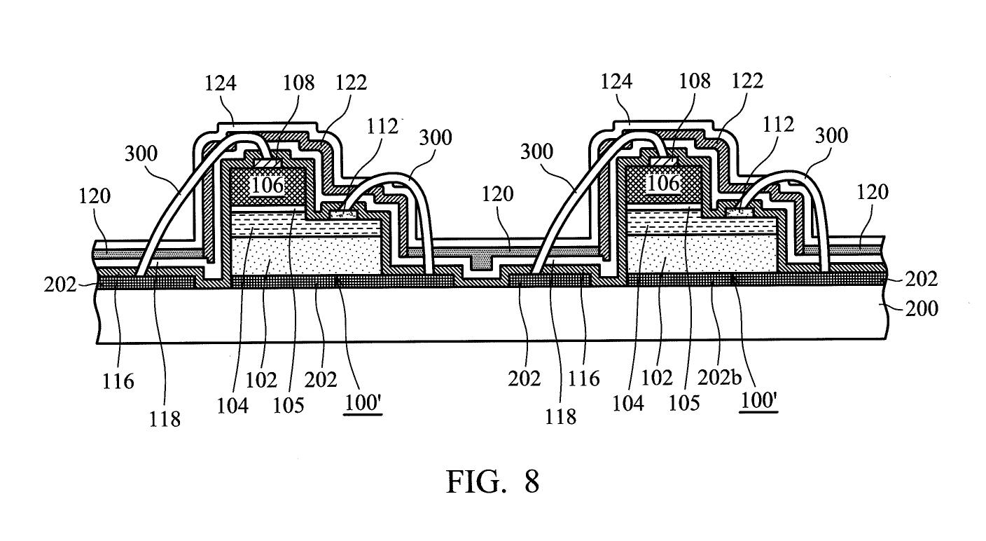

In the method for fabricating the light-emitting diode device shown in FIG. 7, although the LED chips 100 are illustrated as being mounted on the submount 200 in a flip-chip configuration, the method shown in FIGS. 1-7 can be also applied for fabricating a light-emitting diode device having LED chips mounted on the submount 200 by a wire bonding configuration. In FIG. 8, another exemplary LED device having a plurality of LED chips 100′ mounted on the submount 200 by conductive wires 300 is illustrated. In this embodiment, the LED chips 100′ are similar with the LED chips 100 shown in FIGS. 1-7 and comprise a substrate 102, an n-type region 104 formed over the substrate 102, an active region 105 formed on a portion of the n-type region 104, a p-type region 106 formed on the active region 105, a p-contact 108 formed on the p-type region 106, and an n-contact 112 formed on another portion of the n-type region 104, and same titles represent the same components as that described in FIGS. 1-7. The LED chips 100′ can be formed by conventional methods and fabrication thereof are not described here in detail.

In this embodiment, it is noted that the LED chips 100′ are first mounted on the patterned bonding layers 202 formed over the submount 200 by the conductive wires 300, and the transparent insulating layers 116 and 120, the transparent conductive layer 118, and the phosphor layer 122, and the transparent passivation layer 124 are then sequentially formed according to processes illustrated and described in FIGS. 2-7, thereby forming an LED device with an improved phosphor coating and improved electrical reliability, as shown in FIG. 8.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting diode (LED) device, comprising:
a submount;
a light-emitting diode (LED) chip mounted on the submount;
a first transparent insulating layer formed on the submount and the LED chip;
a transparent conductive layer formed on the first transparent insulating layer;
a phosphor layer formed on the transparent conductive layer covering the LED chip; and
a transparent passivation layer formed on the phosphor layer and over the transparent conductive layer.

2. The LED device as claimed in claim 1, wherein the first transparent insulating layer comprises silicon-based or fluorine-based materials.

3. The LED device as claimed in claim 1, wherein the phosphor layer comprises a plurality of phosphor particles entirely coated with a transparent conductive material thereover.

4. The LED device as claimed in claim 1, wherein the transparent passivation layer comprises silicon-based or fluorine-based materials.

5. The LED device as claimed in claim 1, wherein the LED chip is mounted on the submount in a flip-chip configuration

6. The LED device as claimed in claim 1, wherein the LED chip is mounted on the submount in a wire bonding configuration.

7. The LED device as claimed in claim 1, further comprising a second transparent dielectric layer formed on of the transparent conductive layer covering the submount.

8. The LED device as claimed in claim 3, wherein the phosphor particles of the phosphor layer have a diameter of about 10-200 μm.

9. The LED device as claimed in claim 3, wherein the transparent conductive material of the phosphor layer comprises indium tin oxide, aluminum oxide or zinc oxide.

10. The LED device as claimed in claim 1, wherein the first transparent insulating layer is formed with a thickness of about 0.1-10 μm.

11. The LED device as claimed in claim 1, wherein the transparent conductive layer is formed with a thickness of about 0.1-10 μm.

12. The LED device as claimed in claim 1, wherein the transparent passivation is formed with a thickness of about 1 μm to 1 mm.

13. The LED device as claimed in claim 1, wherein the first transparent insulating layer electrically isolates a p-contact of the LED chip from an n-contact of the LED chip.

14. The LED device as claimed in claim 1, wherein the first transparent insulating layer covers exposed surfaces of the LED chip and the submount.
